(19) United States
(12) Patent Application Publication
(10) Pub. No.: US 2006/0261840 A1
(43) Pub. Date: Nov. 23, 2006

(54) System and method for determining channel mobility

(75) Inventors: Siew Kuok Hoon, Dallas, TX (US); Jun Chen, Allen, TX (US)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 11/131,521

(22) Filed: May 18, 2005

(51) Int. Cl. G01R 31/26

(52) U.S. Cl. 324/769

(57) ABSTRACT

A system and method are provided for determining channel mobility. The system includes a threshold voltage (V_{T}) extractor that extracts the V_{T} associated with a metal oxide semiconductor (MOS) transistor and provides an output signal functionally related to the extracted V_{T}. An oscillator generates an oscillating waveform according to the output signal and a calculator computes an estimate of a channel mobility parameter based on the oscillating waveform. A plurality of the V_{T} extractor and oscillators can be distributed across the wafer to provide an indication of channel mobility for different regions of the wafer.

### BACKGROUND

Metal Oxide Semiconductor Field Effect Transistors (MOSFETs) are often used to implement a variety of analog functions and digital logic. For instance, MOSFETs can be arranged to form large scale integrated circuits (LSI) and very large scale integrated circuits (VLSI). A MOSFET can be controlled to provide an output that varies as a function of one or more operating parameters. The drain current (I_{D}) through a given MOSFET device in saturation mode can be expressed as follows:

$${I}_{D} = ( \frac{W}{L} ) \frac{1}{2} μ {{C}_{OX} ( {V}_{GS} - {V}_{T} )}^{2} \qquad Equation 1$$

where
W=channel width of the MOSFET;
L=channel length of the MOSFET;
μ=channel mobility;
C_{OX}=capacitance per unit area of the gate-to-channel capacitor for which the oxide layer serves as a dielectric; and
V_{GS}=gate-to-source voltage of the MOSFET.

Channel mobility μ describes the ease at which electrical carriers (e.g., electrons, holes) drift through the channel of a MOSFET in response to an applied electric field. It is expressed generally as the average electrical carrier drift velocity per unit electric field. Channel mobility μ is an important parameter in characterizing semiconductor materials and in the development of semiconductor devices.

The effective channel mobility can be utilized in ultra-sub-micron channel length device characterization, a particularly critical reliability indicator for device degradation due to hot-carrier effects. The channel mobility factor reveals the information of interface traps charge density and has commonly been characterized using noise spectrum measurements that can be costly. Thus, an improved approach is desired to determine channel mobility for semiconductor devices.

### SUMMARY

A system and method are provided for determining channel mobility. According to one aspect of the present invention, a system includes a threshold voltage (V_{T}) extractor that extracts the V_{T} associated with a metal oxide semiconductor (MOS) transistor and provides an output signal functionally related to the extracted V_{T}. An oscillator generates an oscillating waveform according to the output signal and a calculator computes an estimate of a channel mobility parameter based on the oscillating waveform. A plurality of the V_{T} extractor and oscillators can be distributed across the wafer to provide an indication of channel mobility for different regions of the wafer.

Another aspect of the present invention provides a method for determining channel mobility. The method includes extracting a threshold voltage (V_{T}) associated with a metal oxide semiconductor (MOS) transistor. An output signal is provided that is functionally related to the extracted V_{T}. An oscillating waveform can be generated by a repeated charging and discharging of a capacitor based on the output signal. An estimate of a channel mobility parameter is computed based on the oscillating waveform.

A plurality of mobility extraction circuits can be disposed at different locations across a wafer, and the method can be implemented by providing power to a given one of the plurality of mobility extraction circuits disposed on the wafer (e.g., via one or more probes) to generate a respective oscillating waveform having a characteristic that varies as a function of an extracted V_{T} for the given mobility extraction circuit. The characteristic of the respective oscillating waveform for the given mobility extraction circuit can be measured (e.g., via one or more probes), and the estimate of the channel mobility parameter can be computed for a region of the wafer where the given mobility extraction circuit is disposed based on the measured characteristic.

### BRIEF DESCRIPTION OF THE DRAWINGS

FIG. 1 depicts a block diagram of a system for extracting channel mobility in accordance with an aspect of the present invention.

FIG. 2 depicts an example of an oscillating waveform used for extracting channel mobility in accordance with an aspect of the present invention.

FIG. 3 depicts an example of a mobility extraction circuit for generating an oscillating waveform in accordance with an aspect of the present invention.

FIG. 4 depicts an example of an integrated circuit (IC) die including mobility extraction circuits for extracting channel mobility in accordance with an aspect of the present invention.

FIG. 5 depicts a method for extracting channel mobility in accordance with an aspect of the present invention.

### DETAILED DESCRIPTION

The present invention relates to the calculation of a channel mobility parameter based on an extracted value for the threshold voltage V_{T} of a metal oxide semiconductor (MOS) transistor. A V_{T} value is extracted using a threshold voltage extraction circuit that produces an output signal functionally related to the threshold voltage of an MOS transistor. The output signal is provided as an input to an oscillator circuit which is operative to generate an oscillating waveform based on the output signal. The oscillating waveform could be generated, for example, from the repeated charging and discharging of a capacitor, such as with a current that is derived from the extracted V_{T}. A characteristic of the oscillating waveform, such as a frequency of the oscillating waveform, is measured by a measurement system. A calculator calculates an estimated value for the channel mobility parameter based on the measured characteristic of the oscillating waveform.

The calculation of an estimate of a channel mobility parameter in accordance with an aspect of the present invention can be implemented during the manufacture of integrated circuits (ICs). As an example, the calculation can be performed directly on test ICs disposed on a wafer (e.g., at unused space between individual die). This could enable one or more adjustments to fabrication process control parameters to achieve desired values of a channel mobility parameter. Also, integrated circuits that are manufactured on the same die can be accurately graded as a function of differing channel mobility parameters that may be calculated from different areas of the wafer. Additionally or alternatively, selected ICs from the same wafer can be configured differently, such as to compensate for known variations in channel mobility parameters that are calculated for different regions of the wafer, such as during the manufacturing process or post fabrication.

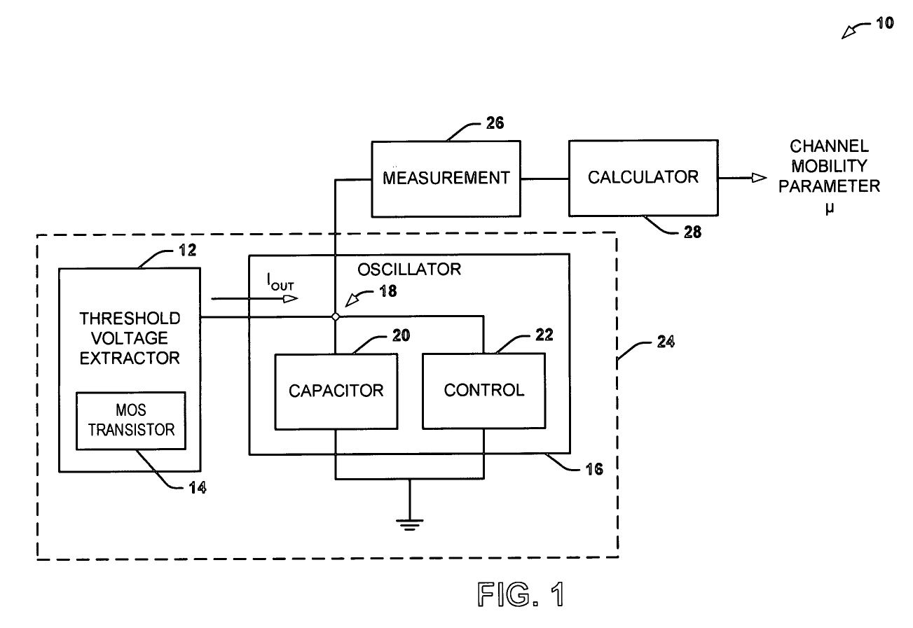

FIG. 1 demonstrates an example of a system 10 for calculating an estimated value for a channel mobility parameter. The system 10 includes a threshold voltage extraction circuit 12 operative to determine a threshold voltage V_{T} of a transistor 14, such as a MOS transistor that is part of the V_{T} extractor. The threshold voltage extraction circuit 12 generates an output current signal I_{OUT}, that is functionally related to the threshold voltage V_{T} of the transistor 14. For example, the threshold voltage V_{T} (or a voltage V_{T} increased by a known input voltage V_{X}) can be supplied as a gate voltage (or gate-to-source voltage) to generate the current I_{OUT}, or I_{OUT} can correspond to mirrored current that is proportional to I_{OUT}.

Various approaches have been developed to determine or extract a threshold voltage V_{T} for a MOSFET. One approach to extract V_{T} is to obtain V_{T} from a single voltage measurement. The efficacy of this method generally depends on the selected current, as different drain currents tend to result in different threshold voltages. Another approach is a linear extrapolation method in which a maximum transconductance is employed to locate a point of maximum slope along a plot of drain current versus gate-source voltage. However, the transconductance is dependent on the series resistance of the MOSFET, which can introduce errors. Other approaches to derive an indication of V_{T} include a ratio method and a quasi-constant-current method, which have various limitations in addition to their complexities.

The output signal I_{OUT} is input to an oscillator circuit 16 at a node 18. The oscillator circuit 16 generates a waveform that is based on the output signal I_{OUT}. In the example of FIG. 1, the oscillator circuit 16 includes a capacitor 20 and a control circuit 22. The control circuit 22 thus controls how the capacitor is charged and discharged by the output signal I_{OUT}. For example, the oscillating waveform acquires a potential that varies relative to a low supply voltage rail (e.g., electrical ground). As an example, the control circuit 22 connects other circuitry (not shown) to the capacitor 20, such that the capacitor 20 is repeatedly charged and discharged from the output signal I_{OUT}. For example, the control circuit 22 could couple the node 18 to high impedance circuitry to permit the capacitor to charge to a predefined high voltage limit, and to low impedance circuitry to allow the capacitor to discharge to a predefined low voltage level. The oscillator circuit 16 can be configured to provide the oscillating waveform at the node 18 according to any of a variety of different types of oscillating waveforms, such as sinusoidal, sawtooth, and the like.

The threshold voltage extractor 12 and the oscillator circuit 16 can be implemented as an integrated circuit 24 on a wafer. The IC 24, including a threshold voltage extractor and oscillator, defines a mobility extraction circuit. For example, a plurality of such ICs 24 could be distributed at desired locations across the wafer. The capacitor 20 can be formed as part of the integrated circuit 24 from a MOS transistor (e.g., a p-channel or n-channel device), such as by shorting the source and drain together. The gate-oxide capacitance of the capacitor will typically be substantially the same as the MOS transistor(s) that are utilized to form the V_{T} extractor 12, which operates to mitigate process variations from the determination of the channel mobility parameter.

The system 10 also includes a measurement system 26 that can be coupled to monitor the oscillating waveform at the node 18. The measurement system 26 measures a characteristic of the oscillating waveform (e.g., frequency). The coupling of the measurement system 26 to the node 18 could be accomplished in a number of ways. As an example, the measurement system 26 could be hardwired to the threshold voltage extraction circuit 12 and the oscillator circuit 16. Alternatively, the measurement system 26 could be a separate and independent piece of hardware (e.g., a test system) that is coupled to the node 18 through one or more probes. The measurement system 26 could also supply power to the threshold voltage extraction circuit 12 as well as measure the characteristic of the oscillating waveform via one or more probes.

A calculator 28 determines an indication of a channel mobility parameter μ based on the measured characteristic of the oscillating waveform. For example, the calculator 28 can compute the channel mobility parameter μ for a region of semiconductor material on a wafer where the IC 24 is formed. Additionally, by implementing a plurality of the IC's 24 across the die, the calculator 28 can determine the channel mobility parameter μ for a plurality of respective regions. The channel mobility parameters may further be utilized to provide a corresponding distribution of channel mobility for the wafer, such as can be utilized for a variety of purposes as described herein.

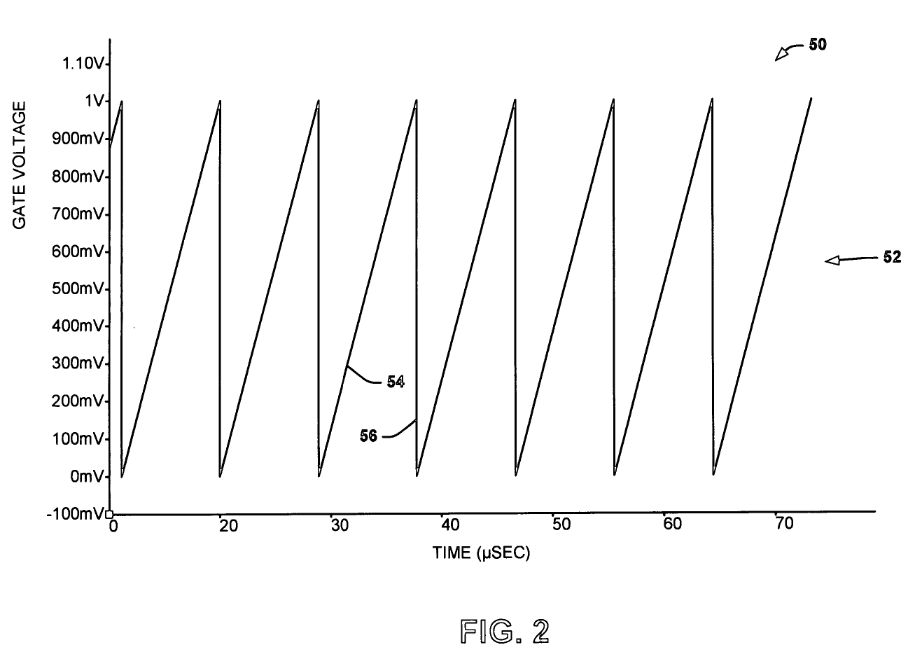

FIG. 2 demonstrates a graph 50 of an example of an oscillating waveform 52, such as could be generated by the oscillator circuit 16 in the example of FIG. 1. The oscillating waveform 52 in the example of FIG. 2 is demonstrated as a sawtooth pattern that includes multiple rising edges 54 and multiple falling edges 56. The rising edges 54 are depicted in the graph 50 as being more gradual than the falling edges 56, generally due to charging a corresponding capacitor voltage linearly. The period or frequency of the waveform can be utilized to determine an estimate of the channel mobility parameter μ. In the example of FIG. 2, the sawtooth pattern 52 has a period of approximately 18 microseconds (μs) that is bounded between approximately 0 and 1 volts. It is to be understood that, in the example of FIG. 2, the illustrated graph is but one example of an oscillating waveform 52 in accordance with an aspect of the invention. However, the graph 50 is not intended to be limited to the example of the sawtooth pattern of FIG. 2. Different slopes of the rising edges and the falling edges, as well as different periods and upper and lower bounds can be realized in accordance with an aspect of the invention. Additionally, different oscillating waveforms can be generated for use according to an aspect of the present invention.

The rising edges 54 could occur as a result of a capacitor being charged, such as by the output signal I_{OUT} charging the capacitor 20 in the example of FIG. 1. Thus, the slope of a rising edge 54 can be a function of the capacitance value of the capacitor and the amplitude of the current of the output signal. As mentioned above, the capacitor can be configured from a MOS transistor (e.g., an n-channel or p-channel device) having gate oxide capacitance per unit area, such that capacitance varies as a function of the channel length and width. The falling edges 56 could occur as a result of the capacitor being discharged, such as by the control circuit 22 coupling the node 18 to the negative supply voltage in the example of FIG. 1.

A characteristic of the oscillating waveform 52 is measured by a measurement system, such as the measurement system 26 in the example of FIG. 1. The characteristic could include the frequency or period of the oscillating waveform 52. Thus a variety of diagnostic tools, such as an oscilloscope, can be employed to measure the frequency or period of the oscillating waveform. A value for the frequency could be obtained by the measurement system, such that the value could be substituted for a variable in an equation to obtain a value for an estimated channel mobility parameter μ.

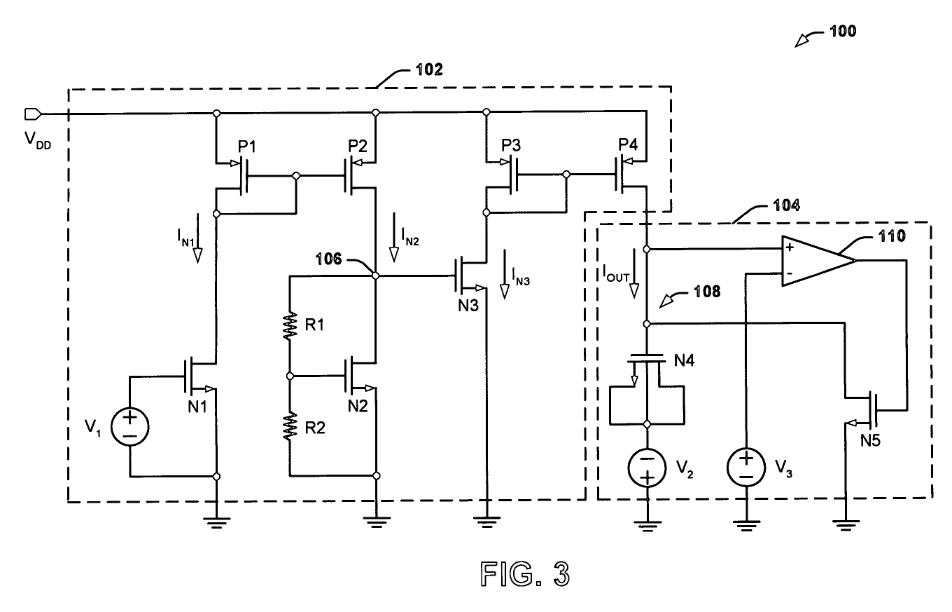

FIG. 3 demonstrates an example of a mobility extraction circuit 100 that can be implemented according to an aspect of the present invention. The mobility extraction circuit 100 includes a threshold voltage extraction circuit 102 and an oscillator circuit 104. The threshold voltage extraction circuit 102 is an example of a way to extract a threshold voltage V_{T} of a transistor, such as a MOS transistor that is included in an IC. The threshold voltage extraction circuit 102 generates an output signal I_{OUT} that is functionally related to the threshold voltage V_{T}. The oscillator circuit 104 generates an oscillating waveform that is based on the output signal I_{OUT}, such as the oscillating waveform 52 demonstrated in the example of FIG. 2.

The threshold voltage extraction circuit 102 includes an NMOS transistor N1 with a source terminal coupled to ground. A voltage supply V₁ is interconnected to provide a fixed gate-to-source voltage (e.g., about 1 volt) to the transistor N1. The voltage supply V₁ thus biases the transistor N1 to provide a drain-to-source current I_{N1} through the transistor N1. The current I_{N1} flows from a positive voltage supply V_{DD} to ground through a PMOS transistor P1. P1 is coupled to another PMOS transistor to form a current mirror with PMOS transistor P2 that supplies a current I_{N2} that is proportional to I_{N1}. The transistors P1 and P1 can be sized so that the corresponding current I_{N2} has a desired ratio to the current I_{N1}. By way of example, the current mirror P1 and P2 can be configured so that the current I_{N2} is approximately equal to the current I_{N1}.

The transistor P2 is coupled between the positive voltage supply V_{DD} and a node 106. The transistor P2 supplies the current I_{N2} to an NMOS transistor N2. The transistor N2 is connected between the node 106 and electrical ground. The gate terminal of the transistor N2 is connected to an intermediate node between a pair of resistors R1 and R2. The resistors R1 and R2 are arranged as a voltage divider between the drain and the source of the transistor N2. That is, the values of the resistors R1 and R2 can be selected to control the voltage at the node 106.

The threshold voltage extraction circuit 102 also includes an NMOS transistor N3 with its gate connected to the node 106 and its source connected to electrical ground. The drain of the transistor N3 is connected to an output current mirror that includes PMOS transistors P3 and P4. Specifically, the drain of the transistor N3 is coupled to the gate and a drain of the PMOS transistor P3. The PMOS transistor P4 has its gate coupled to the gate of the transistor P3 so that P4 supplies a current I_{OUT} that is proportional to the current I_{N3}.

It is to be understood that both the transistors N1 and N2 operate in saturation mode. A saturation mode drain-to-source current can therefore be expressed by the following equations:
I_{DS}=β(V_{GS}−V_{T})² Equation 2
β=(½)*μ*C_{OX}*(W/L) Equation 3
Because the mobility extraction circuit 100 can be manufactured as an IC on a production wafer, all of the transistors in the mobility extraction circuit 100 could be matched, such that they all have substantially the same electrical characteristics (e.g., threshold voltage V_{T}). Additionally, since the currents I_{N1} and I_{N2} are approximately equal to each other, the following equations can be used to express their relationship relative to each other (with numeric subscripts “1” and “2” corresponding to the transistors N1 and N2, respectively):
β₁(V_{GS1}−V_{T})=β₂(V_{GS2}−V_{T}) Equation 4
By sizing the transistor N2 in a manner that the (W/L) term (i.e., width divided by length) of the transistor N2 is four times that of the transistor N1, it is determined that β₂=4*β₁. As an example, by setting the resistors R1=R2, V_{DS2}=2*V_{GS2}, and by setting the voltage supply V₁=1 volt, the following equation can be derived from Equation 4:
V_{DS2}=V_{T}+1=V_{GS3} Equation 5
The relationships of values between the transistors N1 and N2, as well as the magnitude of the voltage supply V₁, are merely examples that have been chosen for mathematical simplicity, and are not intended to limit possible designs that could be implemented in accordance with an aspect of the present invention.

As described above in Equation 5, the voltage V_{DS2} is equal to V_{GS3}, corresponding to the gate-to-source voltage for the transistor N3. Accordingly, the voltage V_{GS3} activates the transistor N3 in saturation, such that a current I_{N3} flows from the positive supply voltage V_{DD} to ground through the transistors P3 and N3. Accordingly, due to the current mirroring effect of the transistors P3 and P4, the current I_{OUT} is provided to the oscillator 104. The output current I_{OUT} thus has a current that is functionally related to the threshold voltage V_{T}. The size of the transistor P3 relative to the transistor P4 can be expressed by a constant K1, such that the (W/L) term of the transistor P3 is proportional to the (W/L) term of the transistor P4 by a factor of K₁. Therefore, combined with Equation 5 above, the following equations can be used to express the relationship between the current I_{OUT} and the current I_{N3}:
I_{OUT}=(1/K₁)*β₃(V_{GS3}−V_{T})² Equation 6
I_{OUT}=(1/K₁)*β₃ Equation 7

The oscillator circuit 104 includes a capacitor implemented as an NMOS transistor N4 with its gate connected to the node 108. The drain and source terminal (and a bulk terminal) are coupled connected together, such that the transistor N4 is configured as a capacitor. The source, drain, and bulk terminals of the transistor N4 are connected to a negative terminal of a voltage supply V₂, with a positive terminal that is connected to ground. Accordingly, the source, drain, and bulk terminals of the transistor N4 are at a negative voltage potential to ensure biasing of the MOS capacitor N4 in the inversion region.

The oscillator circuit 104 also includes a comparator 110 that has a positive input terminal connected to the node 108 and a negative terminal connected to a positive terminal of a voltage supply V₃. The voltage supply V₃ can be configured to supply a positive voltage (e.g., about 1 volt) at the negative terminal of the comparator 110. The comparator 110 has an output that is connected to a gate of an NMOS transistor N5. The transistor N5 has its drain connected to the node 108 and a source terminal connected to ground. Thus, the output of the comparator 110 controls the transistor N5 to provide for charging and discharging the MOS capacitor N4.

For example, the oscillator circuit 104 receives the current I_{OUT} at the node 108, thus charging the MOS capacitor N4. The negative voltage from the supply V₂ ensures that the transistor N4 biases in the inversion region of operation as it charges. The comparator 110 will produce an output that varies in response to the voltage at the node 108 voltage supply V₃ (e.g., +1 volt). For instance, the comparator 110 can activate the transistor N5 when the voltage at the node 108 is greater than the voltage supply V₃, such that the MOS capacitor discharges through the transistor N5. The voltage potential at the node 108 thus rapidly decays to zero, causing the comparator 110 to no longer produce the output as the voltage potential at the node 108 is no longer greater than the voltage potential produced by the voltage supply V₃. The current I_{OUT} then re-charges the MOS capacitor N4 again, producing a corresponding oscillating waveform at the node 108, such as demonstrated in the example of FIG. 2.

The oscillating waveform is functionally related to both the current I_{OUT} and the channel mobility parameter μ. Accordingly, it is at the node 108 that a measurement system can be connected to the mobility extraction circuit 100 to measure a characteristic (e.g., frequency) of the oscillating waveform. An estimate of the channel mobility parameter μ can then be determined as a function of the measured characteristic. For example, a frequency of the oscillating waveform at the node 108 can be measured to ascertain the estimate of the channel mobility parameter μ using the following equation:
f₁₀₈=I_{OUT}/(C₄*V₃) Equation 8

where
f₁₀₈=frequency of the oscillating waveform measured at the node 108;
C₄=capacitance of the MOS capacitor N4;
V₃=reference voltage potential of the voltage supply V₃.
   By way of further example, the size of the transistor N4 relative to the transistor N1 can be expressed by a constant K₂, such that the (W/L) term of the transistor N4 is proportional to the (W/L) term of the transistor N1 by a factor of K₂. The capacitance C₄ of the transistor N4 can therefore be expressed as:
   C₄=C_{OX}*K₂*W₄*L₄ Equation 9
   Therefore, substituting Equations 7 and 9 into Equation 8 results in:
   f₁₀₈=(1/K₁)*(½)*μC_{OX}(W₃/L₃)/(C_{OX}*K₂*W₄*L₄) Equation 10
   By setting W₃=W₄ and L₃=L₄=L, an estimate for the channel mobility parameter μ reduces to the following:
   μ=2*f₁₀₈*K₁*K₂*L Equation 11

As described above, certain terms and parameters have been exemplified at certain values in the example of FIG. 3 in order to simplify the mathematical expressions of Equations 1-11. These terms and parameters, however, should not be considered limitations of calculating an estimate for the channel mobility parameter μ in accordance with an aspect of the invention. It is also to be understood that other designs for the threshold voltage extraction circuit 102 and the oscillator circuit 104 can be realized in accordance with an aspect of the invention. For example, while the example of FIG. 3 is shown and described as an NMOS-based mobility extraction circuit 100, it is to be understood and appreciated that the approach could equally be implemented as PMOS-based topology, including by extracting V_{T} for a corresponding PMOS transistor and utilizing a PMOS capacitor for generating the oscillating waveform. Moreover, various other oscillator topologies could be utilized for generating an oscillating waveform as a function of a corresponding threshold voltage.

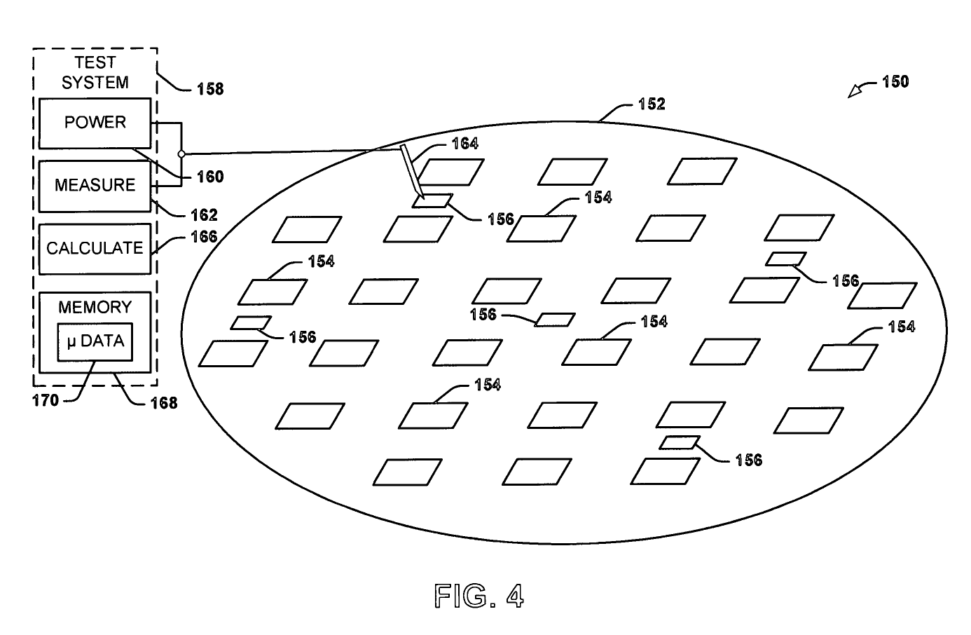

FIG. 4 illustrates an example of a system 150 that can be implemented for calculating an estimate of a channel mobility parameter μ in accordance with an aspect of the invention. The system 150 includes a wafer 152, on which are a plurality of IC die 154. The IC die 154 could include any type of IC manufactured on the wafer 152, such as on a production wafer or test wafer. The system 150 also includes a plurality of mobility extraction circuits 156 disposed at different strategic locations across the wafer 152. For purposes of simplicity of illustration, the spaces between adjacent IC die has been exaggerated for showing the mobility extraction circuits 156. Due to the small size required for implementing the mobility extraction circuits, each of the mobility extraction circuits 156 can be located in scribe lines (or saw lines) between individual IC die 154 of the wafer 152 or other unused space outside of the ICs 154. For instance, each of the mobility extraction circuits 156 could be limited in size since they may be manufactured to fit in scribe lines typically having a width between adjacent die of about 100-150 μm.

In the example of FIG. 4, it is demonstrated that an estimate for a channel mobility parameter μ can be calculated during the manufacture of ICs. As an example, the calculation can be performed for various areas directly on ICs disposed on the wafer 152, such as by providing metal contacts electrically coupled to each of the mobility extraction circuits 156. The system 150 also includes a test system 158. The test system 158 could include a power system 160 and a measurement system 162. The measurement system 162 can be implemented in a manner similar to the measurement system 26 described in the example of FIG. 1. The measurement system 162, for example, could include an oscilloscope or other equipment capable of determining electrical characteristics (e.g., frequency, period, amplitude) of an oscillating waveform. The power element 160 and the measurement system 162 could be manually connected to each of the mobility extraction circuits 156 via a probe 164. The probe 164 could be connected to each of the mobility extraction circuits 156 to supply power from the power system 162 to a given mobility extraction circuit 156, and also to measure a characteristic of an oscillating waveform provided at a given node of the mobility extraction circuit 156. The oscillating waveform has electrical characteristics functionally related to the channel mobility parameter μ, such as described herein.

It is to be understood that the probe 164 could constitute separate probes, each operative to perform a different function. For example, one probe could supply power to the given mobility extraction circuit 156 and a separate probe could measure the characteristic of the oscillating waveform. Additionally, the power system 160 need not be configured as part of the test system 158, but instead could be a device separate from the test system 158, or could be included as part of the probe 164. In addition, those skilled in the art will understand and appreciate various types of probes and associated test systems that could be utilized in accordance with an aspect of the present invention. Those skilled in the art will further understand various controls that can be implemented as part of the test system 158 utilized to control movement of the wafer 152 and/or to effect movement of the probe 164 to activate mobility extraction circuits 156 and to measure corresponding characteristics for such circuits.

The test system 158 could also include a calculator 166, which can be configured to operate similarly to the calculator 28 shown and described in the example of FIG. 1. The calculator 166 could receive the measured characteristic of the oscillating waveform and use it to calculate an estimate of a channel mobility parameter μ. Estimates of a channel mobility parameter μ from various locations across the wafer 152 can be collectively stored as μ data 170 in memory 168 that is part of the test system 158. Therefore, using the μ data 170 corresponding to estimates of a channel mobility parameter μ from various locations across the wafer 152, a distribution of channel mobility across the wafer 152 can be determined (e.g., including identifying variations across the wafer). For example, the μ data 170 could enable adjustments to fabrication process control parameters to achieve desired values of a channel mobility parameter μ. Also, performance of integrated circuits from the wafer 152 can be graded as a function of the calculated channel mobility parameters μ (e.g., higher performance ICs can be graded for sale at higher prices). In addition, selected ICs from the wafer 152 can be configured differently in ways to compensate for variations in channel mobility parameters μ that are calculated.

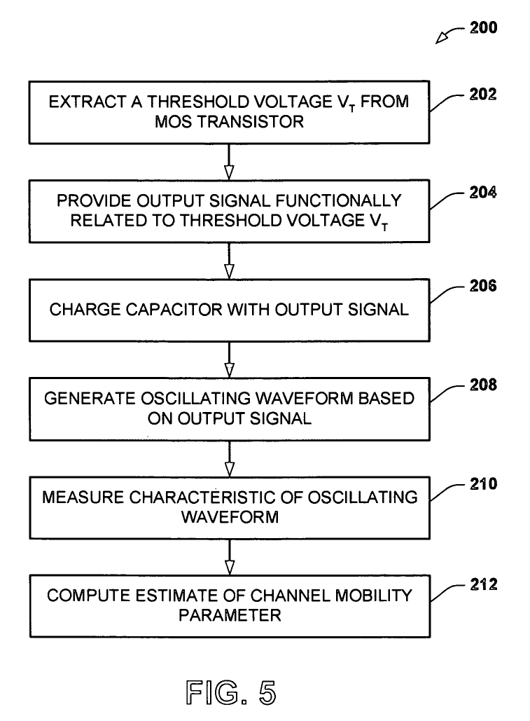

In view of the foregoing structural and functional features described above, certain methods will be better appreciated with reference to FIG. 5. It is to be understood and appreciated that the illustrated actions, in other embodiments, may occur in different orders and/or concurrently with other actions. Moreover, not all illustrated features may be required to implement a method.

FIG. 5 illustrates a method 200 for calculating an estimate of a channel mobility parameter μ in accordance with an aspect of the invention. At 202, a threshold voltage V_{T} is extracted from a MOS transistor. The MOS transistor could be one transistor out of a plurality implemented as part of a threshold voltage extraction circuit on a wafer. An output signal that is functionally related to the threshold voltage V_{T} of the MOS transistor is provided at 204. The output signal could be a current that is generated based on the threshold voltage V_{T}, which can be mirrored to an associated output (e.g., through one or more current mirrors). At 206, a capacitor is charged based on the output signal. The capacitor could be an MOS transistor (PMOS or NMOS) that is configured as a capacitor, and could be a part of an oscillator circuit. An oscillating waveform based on the output signal is generated at 208. For example, the oscillating waveform at 208 could result from a repeated charging and discharging of the capacitor via the output signal. At 210, one or more characteristics of the oscillating waveform are measured. The characteristic of the oscillating waveform could be the frequency or period of the oscillating waveform. At 212, an estimate of a channel mobility parameter μ is computed based on the measured characteristic of the oscillating waveform.

The method 200 can be repeated for each of a plurality of locations on a wafer where corresponding channel mobility extraction circuits have been implemented. The resulting channel mobility parameters can be used in a variety of ways. For example, the characterization of channel mobility provides a convenient and inexpensive means of measuring and predicting device degradation, which can vary depending on channel mobility. Additionally or alternatively, the computed channel mobility can be utilized in configuring an IC that is near the location on a wafer where the channel mobility extraction circuit is situated, such as by providing adaptive voltage control for a digital processor or controlling other circuitry having operation that is dependent on channel mobility. Additionally, or alternatively, fabrication process control parameters can be adjusted to achieve desired channel mobility parameters across the wafer.

What have been described above are examples of the present invention. It is, of course, not possible to describe every conceivable combination of components or methodologies for purposes of describing the present invention, but one of ordinary skill in the art will recognize that many further combinations and permutations of the present invention are possible. For example, while the particular examples shown and described herein generated V_{T} for an N-channel MOS transistor, the approaches and concepts described herein are equally applicable to P-channel MOS transistors. Accordingly, the present invention is intended to embrace all such alterations, modifications, and variations that fall within the spirit and scope of the appended claims.

1. A system for determining channel mobility, comprising:
a threshold voltage (V_{T}) extractor that extracts the V_{T} associated with a metal oxide semiconductor (MOS) transistor and provides an output signal functionally related to the extracted V_{T};
an oscillator that generates an oscillating waveform according to the output signal; and
a calculator that computes an estimate of a channel mobility parameter based on the oscillating waveform.

2. The system of claim 1, further comprising a measurement system that measures a characteristic of the oscillating waveform and provides the measured characteristic to the calculator, the calculator computing the estimate of the channel mobility parameter as a function of the measured characteristic.

3. The system of claim 2, wherein the V_{T} extractor and the oscillator form a mobility extraction circuit that is implemented as an integrated circuit on a wafer, the measurement system further comprising at least one probe that connects to measure the characteristic of the oscillating waveform from the mobility extraction circuit on the wafer.

4. The system of claim 3, wherein the characteristic of the oscillating waveform is at least one of a period or frequency of the oscillating waveform.

5. The system of claim 3, wherein the oscillator further comprises a capacitor that is repeatedly charged and discharged relative to the output signal from the V_{T} extractor to provide the oscillating waveform.

6. The system of claim 5, wherein the MOS transistor is a first MOS transistor and the capacitor comprises a second MOS transistor configured as the capacitor, the capacitor having a gate capacitance, and the first and second MOS transistors being formed on the same integrated circuit (IC).

7. A system for determining channel mobility, comprising:
a threshold voltage (V_{T}) extractor that extracts the V_{T} associated with a metal oxide semiconductor (MOS) transistor and provides an output signal functionally related to the extracted V_{T};
an oscillator that generates an oscillating waveform according to the output signal; and
a calculator that computes an estimate of a channel mobility parameter based on the oscillating waveform further comprising:
a wafer having a plurality of mobility extraction circuits disposed at different locations across the wafer, each of the plurality of mobility extraction circuits comprising:
a respective V_{T} extractor that provides a respective output signal functionally related to a respective extracted V_{T} for a respective MOS transistor; and
a respective oscillator that generates a respective oscillating waveform according to the respective output signal from the respective V_{T} extractor that is associated with the respective oscillator;
a measurement system operative to measure a characteristic of the respective oscillating waveform for each of the plurality of mobility extraction circuits of the wafer, the calculator computing a respective channel mobility parameter as a function of corresponding measured characteristics provided by the measurement system for at least a portion of the plurality of mobility extraction circuits.

8. The system of claim 7, wherein the plurality of mobility extraction circuits are located in scribe line regions of the wafer between individual die on the wafer.

9. The system of claim 7, wherein the measurement system further comprises a probe that is operative to provide power to the plurality of mobility extraction circuits and to measure the characteristic of the respective oscillating waveform for the at least a portion of the plurality of mobility extraction circuits.

10. The system of claim 1, wherein the MOS transistor is a first MOS transistor and the V_{T} extractor further comprises:
a current source comprising the first MOS transistor configured to generate a first current through the first MOS transistor that is proportional to the V_{T} of the first MOS transistor;
a current mirror that mirrors the first current to provide a second current, which is proportional to the first current; and
an output circuit that is configured to provide the output signal based on the second current.

11. A test system, comprising:
a wafer comprising a plurality of mobility extraction circuits disposed at different locations across the wafer, each of the plurality of mobility extraction circuits comprising:
means for extracting a threshold voltage (V_{T}) for an associated metal oxide semiconductor (MOS) transistor and for providing a respective output signal functionally related to the respective extracted V_{T} for a respective one of the different locations; and
means for generating a respective oscillating waveform according to the respective output signal; and
means for measuring a characteristic of the respective oscillating waveform for the plurality of mobility extraction circuits; and
means for computing a respective channel mobility parameter for a respective location of the wafer as a function of the measured characteristic provided by the means for measuring for at least a portion of the plurality of mobility extraction circuits.

12. The system of claim 11, wherein the plurality of mobility extraction circuits are located in scribe line regions on the wafer.

13. The system of claim 11, wherein the means for measuring further comprises:
means for providing power to the plurality of mobility extraction circuits.

14. The system of claim 11, wherein the means for generating further comprises a capacitor that is repeatedly charged and discharged in response to the output signal to provide the respective oscillating waveform.

15. The system of claim 14, wherein the MOS transistor is a first MOS transistor and the capacitor comprises a second MOS transistor configured as a capacitor having a gate capacitance, the first and second MOS transistor for each of the plurality of mobility extraction circuits being formed on the same integrated circuit (IC) of the wafer.

16. The system of claim 11, wherein the measured characteristic of the oscillating waveform comprises at least one of a period or frequency of the respective oscillating waveform.

17. A method for determining channel mobility, the method comprising:
extracting a threshold voltage (V_{T}) associated with a metal oxide semiconductor (MOS) transistor;
providing an output signal that is functionally related to the extracted V_{T};
generating an oscillating waveform by a repeated charging and discharging of a capacitor based on the output signal; and
computing an estimate of a channel mobility parameter based on the oscillating waveform.

18. The method of claim 17, further comprising measuring a characteristic of the oscillating waveform, the estimate of the channel mobility parameter being computed based on the measured characteristic.

19. The method of claim 17, wherein the characteristic of the oscillating waveform is at least one of a frequency or a period of the oscillating waveform.

20. A method for determining channel mobility, the method comprising:
extracting a threshold voltage (V_{T}) associated with a metal oxide semiconductor (MOS) transistor;
providing an output signal that is functionally related to the extracted V_{T};
generating an oscillating waveform by a repeated charging and discharging of a capacitor based on the output signal;
computing an estimate of a channel mobility parameter based on the oscillating waveform, wherein a plurality of mobility extraction circuits are disposed at different locations across a wafer, the method further comprising:
providing power to a given one of the plurality of mobility extraction circuits disposed on the wafer to generate a respective oscillating waveform having a characteristic that varies as a function of an extracted V_{T} for the given mobility extraction circuit; and
measuring the characteristic of the respective oscillating waveform for the given mobility extraction circuit, the estimate of the channel mobility parameter being computed for a region of the wafer where the given mobility extraction circuit is disposed based on the measured characteristic.
